(19) United States
(12) Patent Application Publication
(10) Pub. No.: US 2008/0090052 A1
(43) Pub. Date: Apr. 17, 2008

(54) Nanoimprint Mold, Method of Forming a Nonopattern, and a Resin-Molded Product

(75) Inventors: Masaru Hori, Aichi (JP); Mineo Hiramatsu, Aichi (JP); Hiroyuki Kano, Aichi (JP); Toru Sugiyama, Aichi (JP); Yukihisa Katayama, Aichi (JP); Satoshi Yoshida, Aichi (JP)

Correspondence Address: OLIFF & BERRIDGE, PLC, P.O. BOX 320850, ALEXANDRIA, VA, 22320-4850, US

(73) Assignees: MASARU HORI, Nisshin-shi, Aichi (JP); MINEO HIRAMATSU, Aichi-Gun, Aichi (JP); TOYOTA JIDOSHA KABUSHIK KAISHA, Toyota-shi, Aichi (JP)

(21) Appl. No.: 11/662,074

(22) PCT Filed: Sep. 8, 2005
(86) PCT No.: PCT/JP05/17000

§ 371 Date: Mar. 7, 2007

(30) Foreign Application Priority Data
Sep. 9, 2004 (JP) 2004-262946
Sep. 1, 2005 (JP) 2005-253441

(51) Int. Cl. C23C 16/26; B82B 3/00; G03F 7/00

(52) U.S. Cl. 428/172; 264/241; 264/39; 264/446; 425/90; 425/91; 425/98; 977/887

(57) ABSTRACT

Releasability of a mold and a resin layer during nanoimprinting is improved, thereby improving the durability of the mold. A nanoimprint mold for resin molding comprising a carbon nanowall layer provided on the surface thereof, a method of forming a nanopattern using the mold, and a resin-molded product obtained by the method.

### TECHNICAL FIELD

The present invention relates to a nanoimprint mold, a method of forming a nanopattern, and a resin-molded product obtained by the nanopattern-forming method.

### BACKGROUND ART

It has long been considered that the only way to achieve microfabrication with satisfactory precision and mass productivity was by optical lithography. However, because optical lithography employs propagated light, it is affected by the diffraction limit. For example, in an exposure apparatus with a light source emitting g-line (436 nm) or i-line (365 nm), the maximum resolution has been 0.3 μm to 0.5 μm. To increase the resolution, the wavelength of the exposure light source must be made shorter. For this purpose, research into excimer laser steppers employing KrF (248 nm), ArF (193 nm), and F2 (157 nm), for example, with a view to achieving higher densities in LSIs or the like has been conducted. EUV (comprising X rays of several tens of nanometers) is also being researched as a relevant future technology.

Problems of these technical developments include the inability of the conventional glass materials to support optics, such as lenses, as the wavelength becomes shorter, and the resultant need to develop special materials. There is also the need to develop new resist materials to handle various wavelengths. Furthermore, a great amount of investment must be made in equipment and operational cost that is required by newer generations of the optical lithography technology.

Great expectations are being placed on sub-70 nm or sub-50 nm lithography techniques for the future. In this connection, nanoimprinting has been attempted, which is an application of the press technology used for the mass production of the compact discs or the like to the formation of nanostructures. Nanoimprint technology is capable of achieving a resolution that is on the order of 10 nm, and it can be used for forming micropatterns at very low cost.

Typically, in nanoimprint lithography, a mold with a fine pattern formed on the surface of a substrate made of silicon, for example, is prepared, and the mold is then pressed against a polymer film on another substrate at the glass transition temperature or higher. The polymer film is then cooled and allowed to set, whereby the mold pattern is transferred.

Nanoimprint technology can provide advantages over existing semiconductor microfabrication technologies in that: (1) very fine, highly integrated patterns can be efficiently transferred; (2) the cost of the necessary equipment is low; (3) expensive resists are not required; and (4) complex shapes can be flexibly handled.

As a new material, carbon nanotube is known to be chemically and mechanically strong, and much attention is being focused on it as a material for an electron source. A carbon nanotube consists of one or a plurality of cylinders in a nested structure of graphite carbon atom planes with a thickness of several atoms. It is a very small tube-like substance with an external diameter that is on the nanometer order, and has a length that is on the micrometer order. Carbon nanotubes consisting of a single cylinder are referred to as single-wall nanotubes, and those consisting of a plurality of cylinders in a nested structure are referred to as multiwall nanotubes. Methods for the formation of carbon nanotubes include the arc-discharge method, the CVD method, and the laser abrasion method.

For example, JP Patent Publication (Kokai) No. 2002-234000 A discloses that micropatterns of carbon nanotube film can be easily formed, and that carbon nanotube patterns can be formed with a high level of flatness, with good pattern edge shapes, and with increased reliability in terms of insulation among elements.

### DISCLOSURE OF THE INVENTION

In the conventional nanoimprinting technology, the mold and the resin (resist) that are employed have poor releasability, resulting in various problems, such as a decrease in durability of the mold and breakage of the formed pattern. Although attempts have been made to improve the releasability by subjecting the mold to a surface modification treatment, the situation has remained problematic in that the releasability deteriorates after a dozen or so press operations. Further, when a high aspect-ratio pattern is formed, the area of contract between the mold and a resin layer is particularly large, such that sufficient releasability cannot be achieved.

It is therefore an object of the invention to improve the releasability between the mold and the resin during nanoimprinting and to achieve higher mold durability. It is another object of the invention to provide a novel pattern-forming method based on nanoimprint lithography.

The invention is based on the inventors' realization that the aforementioned objects can be achieved by forming a specific nano-sized structure on a nanoimprint mold. Particularly, it was found that carbon nanowalls (CNWs) are suitable as such nano-sized structures. The carbon nanowall according to the present application is a two-dimensional carbon nanostructure. A typical example has a structure in which walls rise upward in substantially uniform directions from the surface of a substrate. Fullerene (such as C60) can be considered to be a zero-dimensional carbon nanostructure, while carbon nanotubes can be considered to be one-dimensional carbon nanostructures. Although carbon nanofrakes refer to a group of flat fragments with two dimensionalities that are similar to carbon nanowalls, they are more like rose petals and are not mutually connected. The carbon nanoflakes, which are carbon nanostructures, have poorer directionality with respect to the substrate than carbon nanowalls. Thus, carbon nanowalls are carbon nanostructures with totally different characteristics from those of fullerenes, carbon nanotubes, carbon nanohorns, and carbon nanoflakes. Methods of manufacturing carbon nanowalls, for example, will be described later.

In one aspect, the invention provides a nanoimprint mold for resin molding that comprises a carbon nanowall layer on the surface thereof. The mold for resin molding may comprise a substrate on the surface of which a carbon nanowall layer is formed. Alternatively, the mold for resin molding may comprise a transferred product formed on the surface thereof, which transferred product having been transferred using a carbon nanowall layer on a substrate as a mold. Further alternatively, the mold for resin molding may comprise a transferred product formed on the surface thereof, which transferred product having been transferred using another transferred product as a mold, the another transferred product having been transferred using a carbon nanowall layer on a substrate as another mold.

In accordance with the invention, the nanoimprint mold may comprise a metal layer formed on a carbon nanowall layer or a transferred product by electroless plating or electrolytic plating, thereby improving the durability and releasability of the mold. Instead of electroless plating or electrolytic plating, a metal layer can be formed on the carbon nanowall layer or the transferred product using a supercritical fluid. Preferably, the metal layer formed on the carbon nanowall layer or the transferred product by electroless plating or electrolytic plating or by means of supercritical fluid is nitrided or carburized (carbonized).

The carbon nanowall formed on the nanoimprint mold generally has a height of 10 nm to several micrometers and a width of several to several hundreds of nanometers.

In another aspect, the invention provides methods of forming a nanopattern using the aforementioned nanoimprint mold. Specifically, one method comprises growing a carbon nanowall layer on the surface of a mold for resin molding, pressing a resin against the mold on which the carbon nanowall layer is formed, and releasing a resin-molded product from the mold. Another method comprises pressing a resin against a mold for resin molding comprising a transferred product on the surface thereof, the transferred product being transferred using a carbon nanowall layer provided on a substrate as a mold, and releasing a resin-molded product from the mold. Yet another method comprises pressing a resin against a mold for resin molding comprising a transferred product on the surface thereof, said transferred product being transferred using, as a mold, another transferred product that has been transferred using a carbon nanowall layer provided on a substrate as a mold, and releasing a resin-molded product from the mold.

Preferably, the step of growing a carbon nanowall layer on the surface of a mold for resin molding involves plasma CVD. Plasma CVD may be performed at atmospheric pressure so that mass productivity can be improved.

Yet another method of forming a nanopattern comprise growing a carbon nanowall layer on a substrate, releasing the carbon nanowall layer that has been grown from the substrate and then affixing the carbon nanowall layer to the surface of a mold for resin molding, pressing a resin against the mold with the carbon nanowall layer affixed thereto, and releasing a resin-molded product from the mold.

In yet another aspect, the invention provides a resin-molded product with a micropattern transferred to the surface thereof by the method of forming a nanopattern according to any one of the aforementioned methods. Preferably, the micropattern comprises a micro-pillar structure in which submicron-order patterns are arranged.

By thus providing the surface of the mold for resin molding with a carbon nanowall layer, a microstructure of the submicron order can be imprinted on the surface of a resin-molded product. The nanoimprint mold of the invention has superior releasability and durability.

Further, because the resin-molded product molded in accordance with the invention has irregularities of the submicron order that are due to the surface structure of the mold, the resin-molded product has a very large surface area. As a result, the mold has greater adhesion with a paint or adhesive agent and therefore provides an anti-peeling effect, without any change in its exterior look.

### BRIEF DESCRIPTION OF THE DRAWINGS

FIG. 1 schematically shows an apparatus for manufacturing a CNW.

FIG. 2 shows SEM images of a manufactured CNW.

FIG. 3 schematically shows a structure according to the invention.

FIG. 4 shows another example of the structure according to the invention.

FIG. 5 schematically shows a method of forming a nanopattern according to the invention.

FIG. 6 shows steps in an embodiment of the invention.

FIG. 7 shows steps in another embodiment of the invention.

FIG. 8 shows an SEM image of the CNW surface before a Ni electroless plating process.

FIG. 9 shows an SEM image after the Ni electroless plating process.

FIG. 10 shows an SEM image of the surface on the CNW-eliminated side after the elimination of CNW by firing.

### BEST MODE FOR CARRYING OUT THE INVENTION

First, a method for manufacturing a carbon nanowall (CNW) is described.

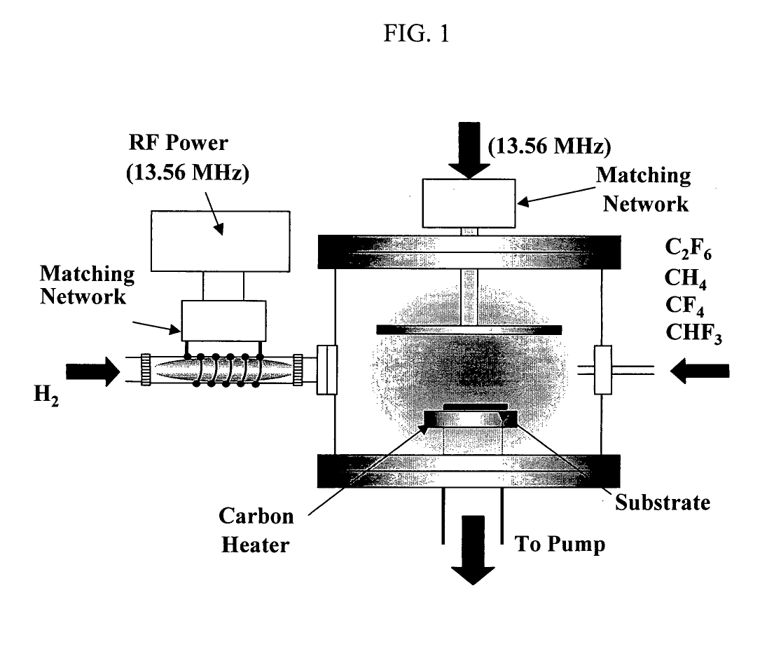

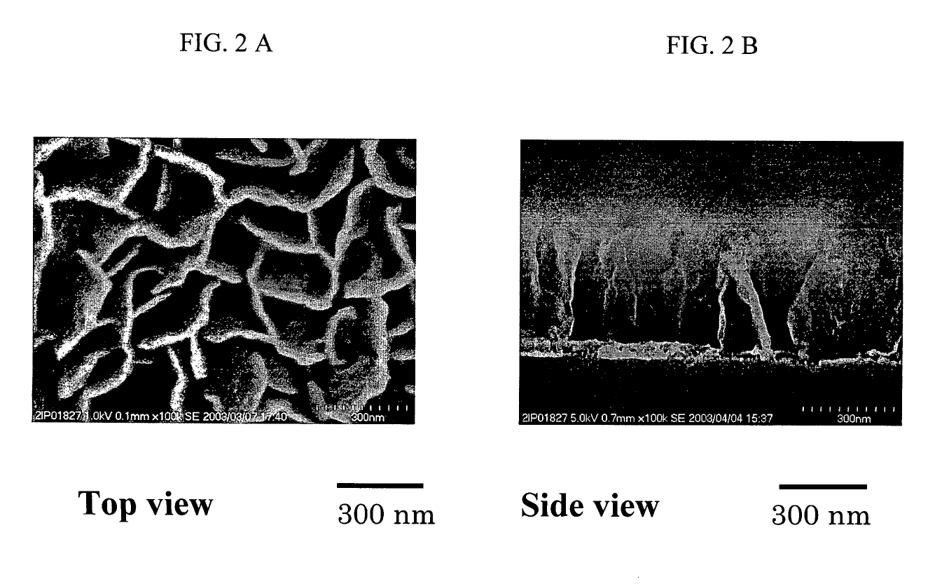

FIG. 1 schematically shows an apparatus for manufacturing a CNW. FIG. 2A and 2B show SEM images of the CNW manufactured using the apparatus of FIG. 1. With reference to FIG. 1, H radicals as well as a reaction gas containing carbon, such as CF₄, C₂F₆, or CH₄, are introduced between parallel flat-plate electrodes in a chamber. PECVD (plasma enhanced chemical vapor deposition) is then performed, when the substrate is preferably heated to approximately 500° C. The parallel flat-plate electrodes are spaced apart from one another by 5 cm. Between the electrodes, there is produced a capacitively coupled plasma, using high-frequency output equipment 13.56 MHz and an output power of 100 W. The H radicals are formed within a silica tube with a length of 200 mm and an internal diameter φ of 26 mm, into which H₂ gas is introduced so as to produce an inductively coupled plasma using high-frequency output equipment of 13.56 MHz and an output power of 400 W. The flow rate of the material gas and the H₂ gas is 15 sccm and 30 sccm, respectively. The pressure inside the chamber is 100 mTorr. When a CNW was grown in this system for 8 hours, its height (CNW film thickness) was 1.4 μm. This, however, is merely an example and is not to be taken as limiting the experimental conditions, equipment, or the results of the invention.

The invention will be described in detail below with reference to the drawings.

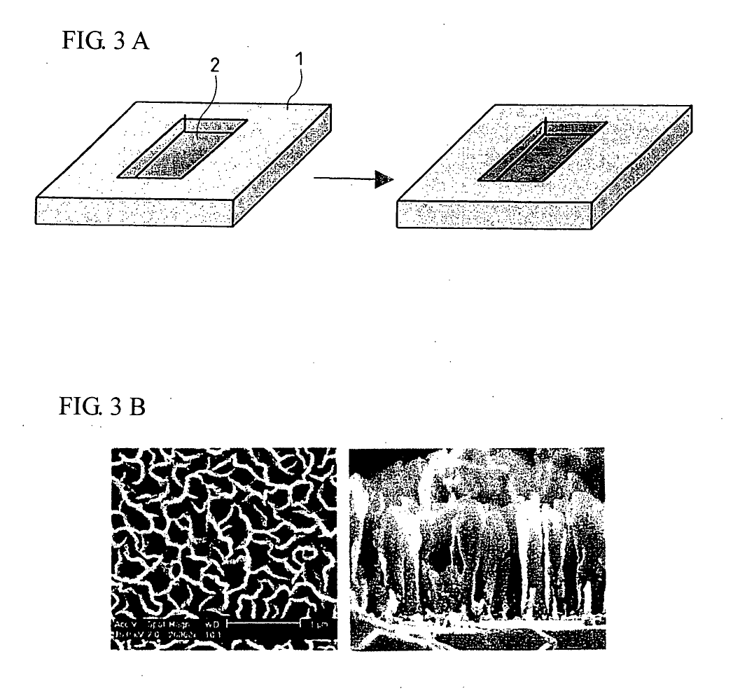

FIG. 3 schematically shows a mold according to the invention. As shown in FIG. 3A, a nanoimprint mold 1 comprises a resin-molding portion 2 in which a carbon nanowall layer is to be formed. Alternatively, a separately manufactured carbon nanowall layer is affixed to the resin-molding portion 2. FIG. 3B shows SEM images of the surface of the mold, one providing a top view and the other a lateral view of the carbon nanowall layer.

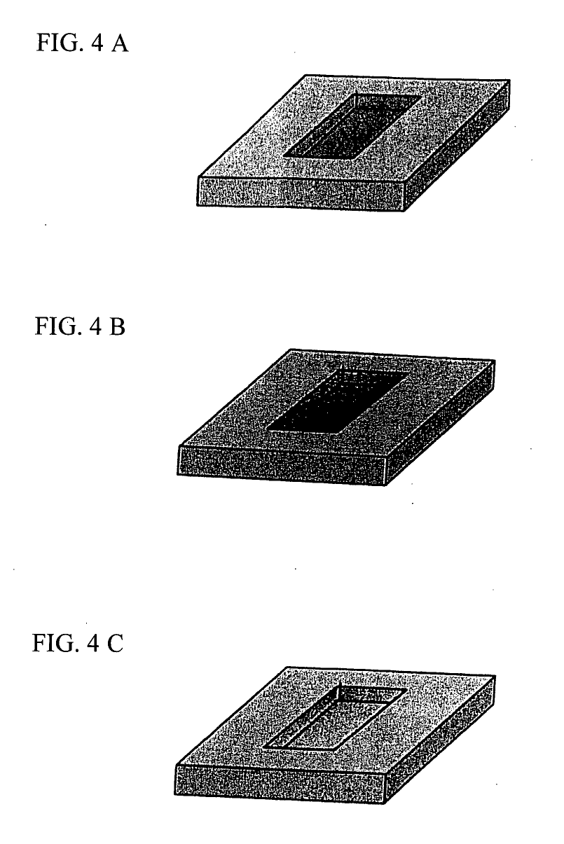

FIG. 4 shows another example of the mold of the invention. A mold is prepared, as shown in FIG. 4A. A carbon nanowall layer is then formed on the surface of the mold, as shown in FIG. 4B. Alternatively, a separately manufactured carbon nanowall layer is affixed to the mold surface. Referring to FIG. 4C, the carbon nanowall layer is subjected to a metal plating process or a metal embedding process involving a supercritical fluid in which organic metal is dissolved. These processes are performed so as to provide the mold surface with submicron-order irregularities with a large aspect ratio. The metal surface may be further hardened by nitriding or carburizing, preferably using plasma processes, such as ion plating.

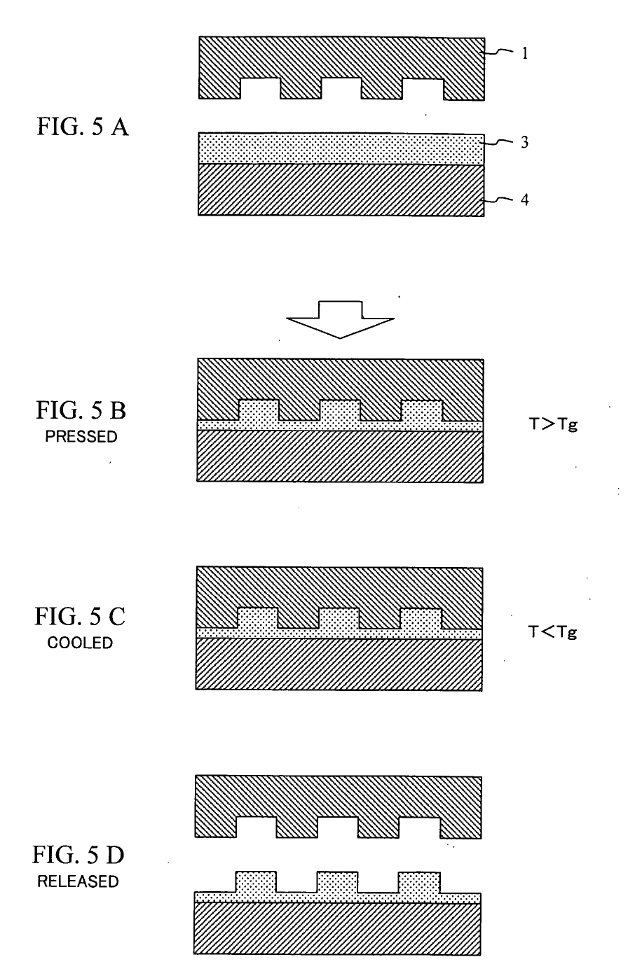

FIG. 5 shows a method of forming a nanopattern according to the invention. FIG. 5A shows the step of preparing a mold 1 on which a carbon nanowall layer is formed, and a molded product consisting of a substrate 4 on which a resin layer 3 is provided. FIG. 5B shows the step of heating the mold 1 with the carbon nanowall layer and the molded product with the resin layer 3 formed on the substrate 4 to the glass transition temperature (Tg) of the resin or higher, followed by a pressing operation. FIG. 5C shows the step of cooling the mold and the resin-molded product to the glass transition temperature (Tg) of the resin or below. FIG. 5D shows the step of releasing the resin-molded product from the mold.

The type of resin used with the method of forming a nanopattern according to the invention is not particularly limited, and any material that can be softened and formed at a predetermined transition temperature (Tg) or above can be used. Specifically, examples include: thermoplastic resins, such as polyethylene, polypropylene, polyvinyl alcohol, polyvinylidene chloride, polyethylene terephthalate, polyvinyl chloride, polystyrene, ABS resin, AS resin, acryl resin, polyamide, polyacetal, polybutylene terephthalate, polycarbonate, modified polyphenylene ether, polyphenylene sulfide, polyether ether ketone, liquid crystalline polymer, fluorine resin, polyarete, polysulfone, polyether sulfone, polyamide-imide, polyether imide, and thermoplastic polyimide; thermosetting resins, such as phenol resin, melamine resin, urea resin, epoxy resin, unsaturated polyester resin, alkyd resin, silicone resin, diallyphthalate resin, polyamidebismaleimide, and polybisamide triazole; and a mixture of two or more of the aforementioned materials.

While the invention is described hereafter with reference to specific embodiments thereof, it should be apparent to those skilled in the art that the invention is not limited by those embodiments.

### EMBODIMENT 1

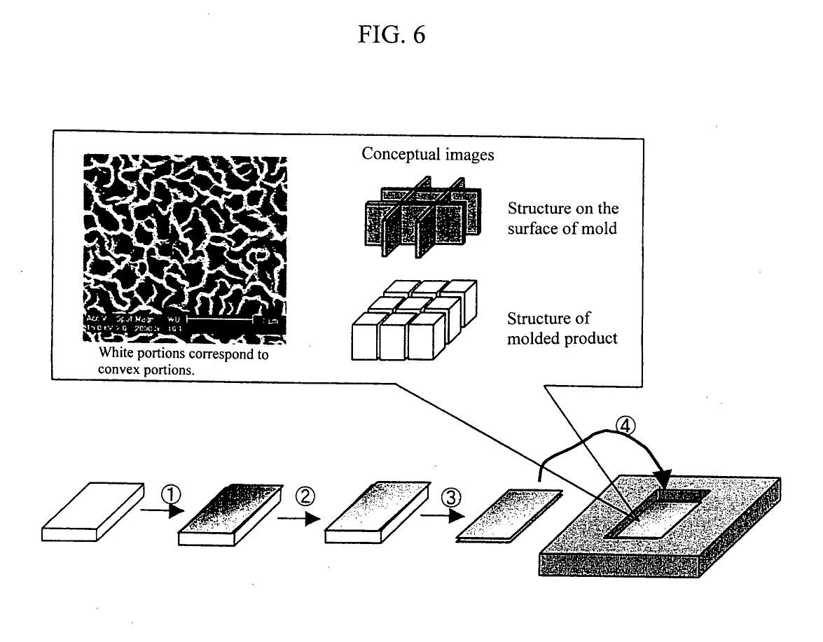

A mold structure with a CNW-patterned mold was prepared. In the present embodiment, the convex portions of the CNW correspond to the concave portions of a molded product. With reference to FIG. 6, a CNW was fabricated on a substrate for producing a CNW under the conditions described above with reference to a method of manufacturing a CNW (1). This was followed by the Ni-plating of the surface of the CNW (2). The plating process may involve substance other than Ni. Then, the CNW was peeled from the substrate (3). Alternatively, the CNW may be partly burned for removal. Finally, the CNW was fixed to the surface of the mold.

In the present embodiment, the white portions of the SEM image of the CNW correspond to the convex portions of the resin-molded product, as shown in the conceptual images in the drawing.

### EMBODIMENT 2

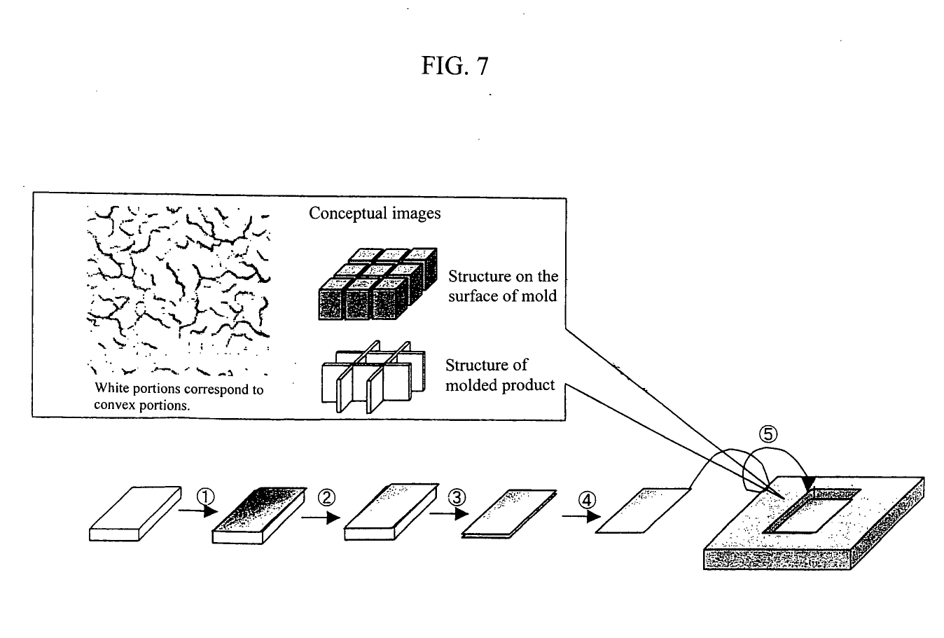

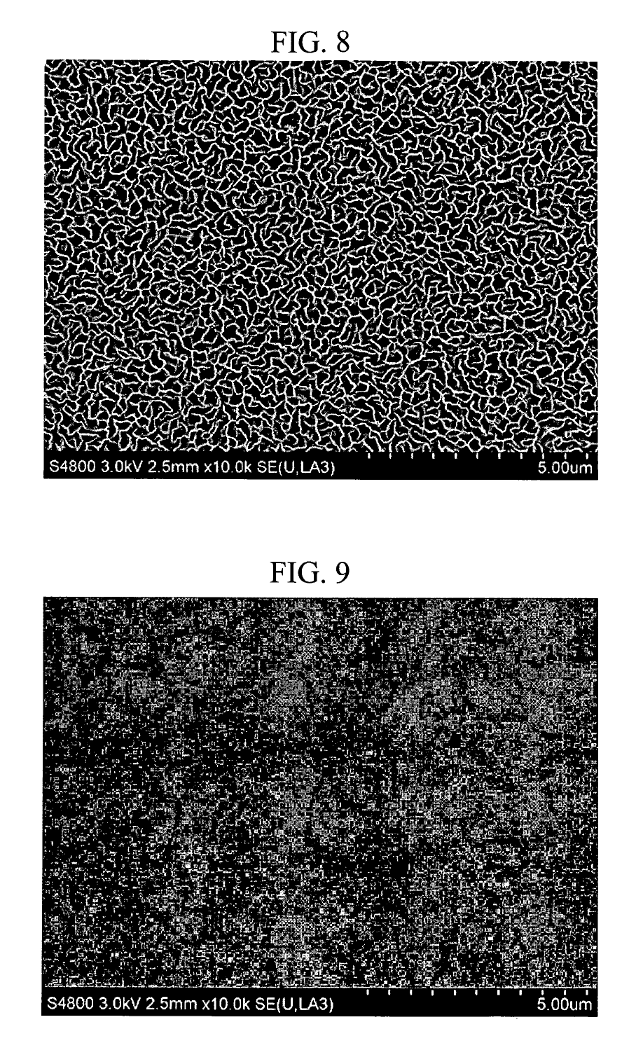

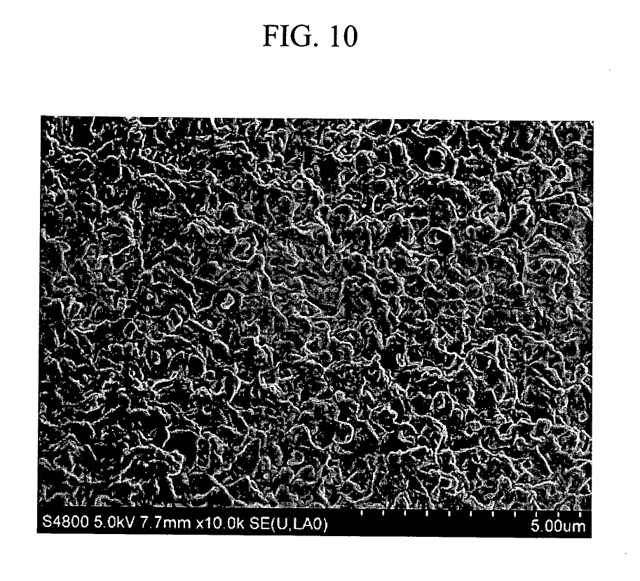

As shown schematically in FIG. 7, a mold structure with a reversed CNW-patterned mold was prepared. In the present embodiment, the convex portions of the CNW directly correspond to the convex portions of a molded product. Initially, a CNW was manufactured (1) on a substrate for producing a CNW under the conditions described with reference to the aforementioned method for forming a CNW. FIG. 8 shows an SEM image of the CNW surface prior to the Ni electroless plating process. Then, the surface of the CNW was provided with a Ni plating (2). FIG. 9 shows an SEM image of the CNW surface after the Ni electroless plating process. The plating process may involve a substance other than Ni. The CNW was then peeled from the substrate (3). FIG. 10 shows an SEM image of the surface on the CNW-removed side after the elimination of CNW by firing. It is seen from FIG. 10 that a reversed pattern of CNW is clearly present. The remaining CNW was burned at 700° C. in the air. Finally, the CNW was fixed to the surface of the mold with the side opposite to the plated layer facing the outside.

In the present embodiment, the white portions of the SEM image of the CNW correspond to the convex portions of the resin-molded product, as shown in the conceptual images in the drawing.

Industrial Applicability

In accordance with the invention, the releasability and durability of a nanoimprint mold can be improved, thereby contributing to the practical application of the next-generation microstructure fabrication technology.

1. A nanoimprint mold for resin molding, comprising a carbon nanowall layer provided on the surface thereof.

2. A nanoimprint mold for resin molding, comprising a transferred product on the surface thereof that has been transferred using a carbon nanowall layer formed on a substrate as a mold.

3. A nanoimprinting mold for resin molding, comprising a transferred product on the surface thereof that has been transferred using another transferred product, as a mold, that has been transferred using a carbon nanowall layer formed on a substrate as a mold.

4. The nanoimprint mold according to claim 1, wherein said carbon nanowall layer or said transferred product is provided with a metal layer by electroless plating or electrolytic plating.

5. The nanoimprint mold according to claim 1, wherein said carbon nanowall layer or said transferred product is provided with a metal layer using a supercritical fluid.

6. The nanoimprint mold according to claim 1, wherein a metal layer provided on said carbon nanowall layer or said transferred product by electroless plating, electrolytic plating, or using a supercritical fluid is nitrided.

7. The nanoimprint mold according to claim 1, wherein a metal layer provided on said carbon nanowall layer or said transferred product by electroless plating, electrolytic plating, or using a supercritical fluid is carburized (carbonized).

8. The nanoimprint mold according to claim 1, wherein said carbon nanowall has a height of 10 nm to several micrometers and a thickness of several to tens of hundreds of nanometers.

9. A method of forming a nanopattern comprising:
growing a carbon nanowall layer on the surface of a mold for resin molding;
pressing a resin against said mold on which said carbon nanowall layer is formed; and
releasing a resin-molded product from said mold.

10. A method of forming a nanopattern comprising:
pressing a resin against a mold for resin molding comprising a transferred product on the surface thereof, said transferred product being transferred using a carbon nanowall layer provided on a substrate as a mold; and
releasing a resin-molded product from said mold.

11. A method of forming a nanopattern comprising:
pressing a resin against a mold for resin molding comprising a transferred product on the surface thereof, said transferred product being transferred using, as a mold, another transferred product that has been transferred using a carbon nanowall layer provided on a substrate as a mold; and
releasing a resin-molded product from said mold.

12. The method of forming a nanopattern according to claim 9, wherein the step of growing a carbon nanowall layer on the surface of a mold for resin molding involves plasma CVD.

13. The method of forming a nanopattern according to claim 12, wherein said plasma CVD is performed at atmospheric pressure.

14. A method of forming a nanopattern comprising:
growing a carbon nanowall layer on a substrate;
releasing said carbon nanowall layer that has been grown from said substrate and then affixing said carbon nanowall layer to the surface of a mold for resin molding;
pressing a resin against said mold with said carbon nanowall layer affixed thereto; and
releasing a resin-molded product from said mold.

15. A resin-molded product with a micropattern transferred to the surface thereof by the method of forming a nanopattern according to claim 9.

16. The resin-molded product according to claim 15, wherein said micropattern comprises a micro-pillar structure in which submicron-order patterns are arranged.
